(19) United States
(12) Patent Application Publication
(10) Pub. No.: US 2011/0186128 A1
(43) Pub. Date: Aug. 4, 2011

(54) SOLAR CELL ELEMENT HEAT DISSIPATION EFFICIENCY MEASUREMENT SYSTEM AND METHOD

(75) Inventors: Zun-Hao Shih, Taoyuan (TW); Hwen-Fen Hong, Taoyuan (TW)

(73) Assignee: Institute of Nuclear Energy Research, Atomic Energy Council, Executive Yuan, Longtan Township (TW)

(21) Appl. No.: 12/699,090

(22) Filed: Feb. 3, 2010

(51) Int. Cl. H01L 31/00

(52) U.S. Cl. 136/259

(57) ABSTRACT

A solar cell element heat dissipation efficiency measurement system and method, such that the adverse influence on the accuracy and stability of heat dissipation efficiency measurement of a solar cell element due to outdoor environment variations and sunlight illumination differences can be avoided effectively. The solar cell element heat dissipation efficiency measurement system, comprising: a solar cell element, placed in a room of constant temperature and constant humidity, with its backside sprayed with a material of high emission coefficient; a power supply, that is used to applied a forward bias on the solar cell element, so as to make the solar cell element produce a forward bias current to become a stable heat source; and an infrared camera, used to detect the temperature variations and distributions of the solar cell element.

### BACKGROUND OF THE INVENTION

1. Field of the Invention

The present invention relates to a heat dissipation efficiency measurement system and method, and in particular to a solar cell element heat dissipation efficiency measurement system and method.

2. The Prior Arts

Along with the increase of demand for energy and the emergence of the problem of global warming, the various alternative energy resources that can be utilized perpetually and are environment friendly such as, wind energy, hydraulic energy, biomass energy, geothermal energy, tide-wave energy, and solar energy, have caught the attention of the world in recent years, and various efforts and researches have been dedicated to the conversion and application technologies of these energy resources. Among them, the solar energy has the most promising prospect for further development, since sunlight can be converted directly into electricity for utilization without having to install additional devices.

Refer to FIG. 1 for a schematic diagram of measuring the heat dissipation efficiency of a solar cell element according to the prior art. In general, a solar cell chip 10 is disposed on a ceramic substrate 12 to form a sub-solar cell element 14. Then, the sub-solar cell element 14 is weld on an aluminum heat dissipation plate 16 to form a solar cell element 18.

In operation, a concentrator lens 20 of a concentrator type solar cell module 19 is used to focus and concentrate sunlight and its energy onto the solar cell chip 10. However, since the photo-electric conversion efficiency of the solar cell chip 10 is not capable of reaching 100%, such that the remaining sunlight energy that can not be converted to electrical energy is dissipated as heat onto an aluminum heat dissipation plate 16. As such, the heat dissipation efficiency of the aluminum heat dissipation plate 16 will affect the photo-electrical conversion efficiency of a solar cell chip 10. Therefore, the heat dissipation management of the aluminum heat dissipation plate 16 has a great impact on the photo-electric conversion efficiency of the solar cell unit 18.

Presently, the measurement of heat dissipation efficiency of a solar cell element is realized in the following ways: firstly, a material of high emission coefficient 22 is sprayed on the backside of an aluminum heat dissipation plate 16; next, the solar cell element 18 is put outdoors to gather sunlight by means of a concentrator lens 20, such that sunlight will irradiate directly on the solar cell chip 10; then, an infrared camera 24 is used to measure the temperature of the aluminum heat dissipation plate 16. However, usually, the conditions of outdoor measurement environments vary enormously, such as temperature differences, instantaneous wind speeds, and sunlight illumination differences, that could affect the accuracy and stability of measurement of heat dissipation efficiency of a concentrator type solar cell module 19, thus resulting in quite a lot of deviations in the data gathered, such that there is no way of determining the heat dissipation efficiency of a solar cell element 18.

In view of the problems and shortcomings of the prior art, the present invention discloses a solar cell element heat dissipation efficiency measurement system and method, so as to overcome the problems of the prior art.

### SUMMARY OF THE INVENTION

A major objective of the present invention is to provide a solar cell element heat dissipation efficiency measurement system and method, such that the adverse influence on the accuracy and stability of heat dissipation efficiency measurement of a solar cell element due to outdoor environment variations and sunlight illumination differences can be avoided effectively.

Another objective of the present invention is to provide a solar cell element heat dissipation efficiency measurement system and method, such that in applying a forward bias on the solar cell element so as to make the solar cell chip emit light, the uniformity of light emitted from the surface of the solar cell chip can be observed at the same time, so as to determine the structural uniformity of the solar cell chip.

In order to achieve the above-mentioned objective, the present invention provides a solar cell element heat dissipation efficiency measurement system, comprising: a solar cell element, placed in a room of constant temperature and humidity, with its backside sprayed with material of high emission coefficient; a power supply, that is used to applied a forward bias on the solar cell element, so as to make the solar cell element produce a forward bias current to become a stable heat source; and an infrared camera, used to detect the temperature variations and distributions of a solar cell element.

Moreover, the present invention provides a solar cell element heat dissipation efficiency measurement method, comprising the following steps: firstly, providing a solar cell element, with its backside sprayed with a material of high emission coefficient; next, placing the solar cell element in a room of constant temperature and humidity; then, applying a forward bias on the solar cell element through utilizing a power supply, so as to make the solar cell element to produce a forward bias current to become a heat source; and finally, utilizing an infrared camera to detect the temperature variations and distributions of the solar cell element.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram for a system of measuring the heat dissipation efficiency of a solar cell element according to the prior art;

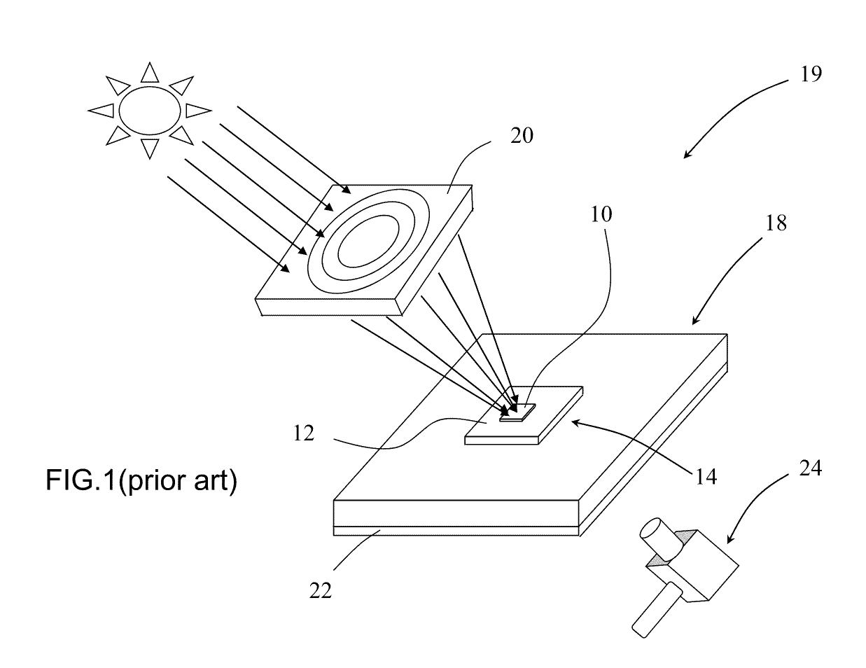

FIG. 2 is a schematic diagram of a structure of the solar cell element heat dissipation efficiency measurement system according to the present invention; and

FIG. 3 is a flowchart of the steps of a solar cell element heat dissipation efficiency measurement method according to the present invention.

### DETAILED DESCRIPTION OF THE PREFERRED EMBODIMENT

The purpose, construction, features, functions and advantages of the present invention can be appreciated and understood more thoroughly through the following detailed descriptions with reference to the attached drawings.

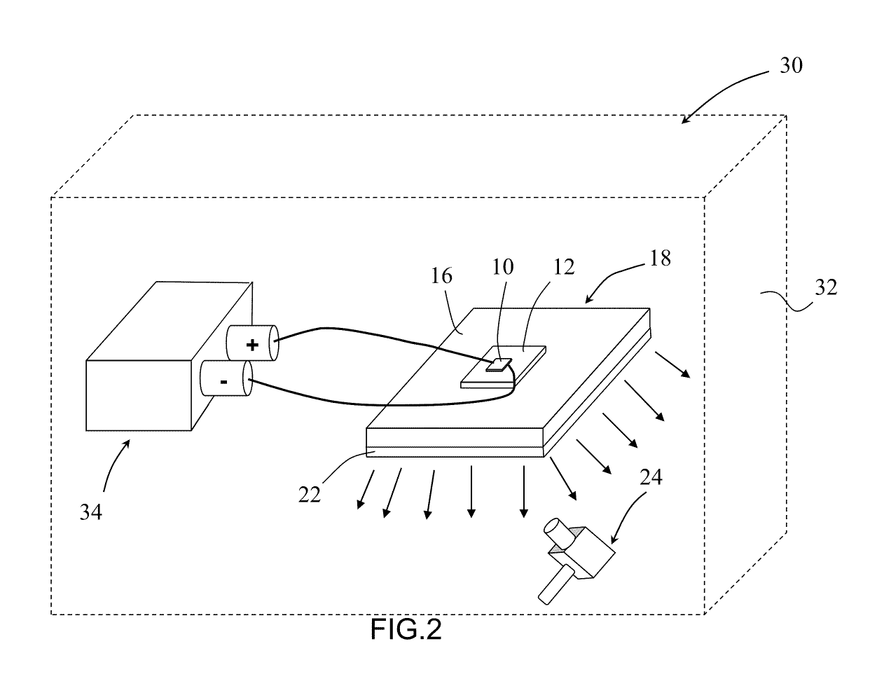

Refer to FIG. 2 for a schematic diagram of a structure of the solar cell element heat dissipation efficiency measurement system according to the present invention. As shown in FIG. 2, the solar cell element heat dissipation efficiency measurement system 30 comprising: a room 32 of constant temperature and constant humidity; a solar cell element 18 placed in the room 32 and includes a solar cell chip 10, a ceramic substrate 12 used to mount the solar cell chip 10, an aluminum heat dissipation plate 16 for the ceramic substrate 12 to be welded thereon, and having its backside sprayed with a material of high emission coefficient 22; a power supply 34, that is used to apply a forward bias to the solar cell element 18 to generate a forward bias current, so as to make the solar cell element 18 a stable heat source; and an infrared camera 24, used to detect the temperature variations and distributions of the aluminum heat dissipation plate 16.

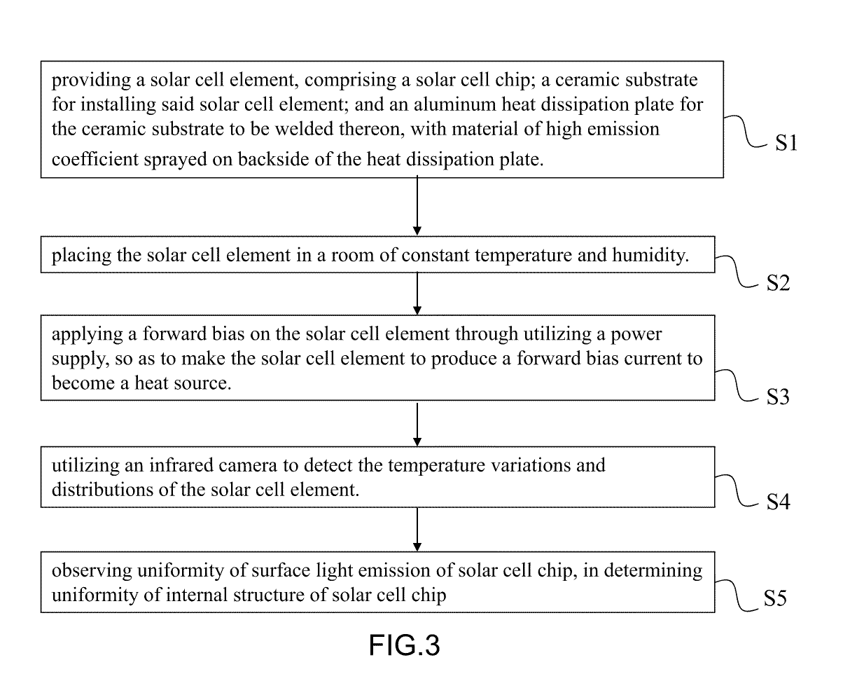

Refer to FIGS. 2 and 3 at the same time, wherein, FIG. 3 is a flowchart of the steps of a solar cell element heat dissipation efficiency measurement method according to the present invention, comprising the following steps: firstly, as shown in step S1, providing a solar cell element 18, the solar cell element 18 includes a solar cell chip 10, a ceramic substrate 12 used to mount the solar cell chip 10, an aluminum heat dissipation plate 16 for the ceramic substrate 12 to be welded thereon, and having its backside sprayed with a material of high emission coefficient 22; next, as shown in step S2, placing the solar cell element 18 in a room 32 of constant temperature and constant humidity; then, as shown in step S3, applying forward bias on the solar cell element 18 through utilizing a power supply 34, so as to make the solar cell chip 10 produce a forward bias current to become a heat source; and finally, as shown in step S4, detecting the temperature variations and distributions of the aluminum heat dissipation plate 16 by means of an infrared camera 24.

Since the heat produced by the solar cell element 18 under a forward bias tends to dissipate, therefore, in the present invention, for the material of high emission coefficient 22 sprayed on the backside of the aluminum heat dissipation plate 16, a black lacquer of emission rate of 0.94 is utilized, so as to emit the heat absorbed. Meanwhile, the value of the forward bias current is equal to 1.25 times the short circuit current value measured, when the outdoor sunlight illumination of the solar cell chip 10 is 850 W/m².

In the present invention, a power supply 34 is utilized to apply a forward bias on a solar cell element 18 in an indoor environment of constant temperature and constant humidity, so as to make the solar cell chip produce a forward bias current. Since the epitaxial layer of the solar cell chip 10 is a PN junction diode, therefore, the composite electron-hole pairs contained therein are capable of producing energy of light, however, the light emission rate of the epitaxial layer is not 100%. Therefore, the remaining electron-hole pairs will generate and dissipate heat after combination. As such, in a stable condition, the solar cell chip 10 can be considered as a stable heat source, just like in an outdoor operation environment, the solar cell chip can also be considered as a heat source, however, in a stable indoor environment, the heat dissipation efficiency of the solar cell element 18 is dependent mainly on the heat dissipation medium (namely, the aluminum heat dissipation plate 16) utilized, such that the factor of outside environment affecting the heat dissipation efficiency of the solar cell element can be reduced to the minimum, thus the accuracy of measuring heat dissipation efficiency of the solar cell element can be increased without being affected by the outside weather conditions.

Moreover, in situation that enormous amount of impurities are included in the crystal growth process of the solar cell chips 10, thus resulting in defects in crystal structure, and that would in turn cause the un-uniformity of light energy produced by the composite electron-hole pairs, as such, the surface illuminance of the solar cell chip will not be uniform. In the present invention, a power supply is used to apply forward bias on the solar cell chip 10 to make it produce forward bias current, so as to make it emit light. Therefore, as described in step S5 of FIG. 3, through observing the uniformity of light emitted from the surface of the solar cell chip 10, the uniformity of internal structure of the solar cell chip 10 can be determined.

Summing up the above, the present invention provides a brand new solar cell element heat dissipation efficiency measurement system and method, such that in an indoor environment of constant temperature and constant humidity, a forward bias is applied on a solar cell element, so as to make the solar cell element as a stable heat source, then an infrared camera is used to observe the temperature variations and distributions of the solar cell element, hereby avoiding effectively that the accuracy and stability of solar cell element heat dissipation measurement being affected by the variations of outdoor environment and sunlight illuminance differences.

Furthermore, through the application of solar cell element heat dissipation efficiency measurement system and method of the present invention, such that when applying a forward bias on the solar cell element, the uniformity of light emitted from the surface of solar cell chip can be observed, so as to determine the structure uniformity of the solar cell chip.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A solar cell element heat dissipation efficiency measurement system, comprising:
a solar cell element, disposed in a room of constant temperature and constant humidity, with its backside sprayed with a material of high emission coefficient;
a power supply, used to apply a forward bias on said solar cell element, so as to make said solar cell element produce a forward bias current to become a stable heat source; and
an infrared camera, used to detect temperature variations and distributions of said solar cell element.

2. The solar cell element heat dissipation efficiency measurement system as claimed in claim 1, wherein
said solar cell element includes a solar cell chip, a substrate for installing said solar cell chip, and a heat dissipation plate for said substrate to be welded thereon, and said material of high emission coefficient is sprayed on said backside of said heat dissipation plate.

3. The solar cell element heat dissipation efficiency measurement system as claimed in claim 2, wherein
said substrate is made of ceramic material.

4. The solar cell element heat dissipation efficiency measurement system as claimed in claim 2, wherein
said heat dissipation plate is made of aluminum.

5. The solar cell element heat dissipation efficiency measurement system as claimed in claim 1, wherein
when said solar cell element emits light upon being applied a forward bias, structure quality of said solar cell chip is determined through observing uniformity of surface light emission of said solar cell chip.

6. The solar cell element heat dissipation efficiency measurement system as claimed in claim 1, wherein
value of said forward bias current is equal to 1.25 times a short circuit current value measured, when outdoor sunlight illuminance of said solar cell chip is 850 W/m².

7. The solar cell element heat dissipation efficiency measurement system as claimed in claim 1, wherein
said material of high emission coefficient is a black lacquer of emission rate of 0.94.

8. A solar cell element heat dissipation efficiency measurement method, comprising following steps of:
providing a solar cell element, and spraying a material of high emission coefficient on a backside of said solar cell element;
placing said solar cell element in a room of constant temperature and constant humidity;
applying a forward bias on said solar cell element through utilizing a power supply, so as to make said solar cell element produce a forward bias current to become a heat source; and
detecting temperature variations and distributions of said solar cell element through utilizing an infrared camera.

9. The solar cell element heat dissipation efficiency measurement method as claimed in claim 8, wherein
said solar cell element includes a solar cell chip, a substrate for installing said solar cell chip, and a heat dissipation plate for said substrate to be welded thereon, and said material of high emission coefficient is sprayed on said backside of said heat dissipation plate.

10. The solar cell element heat dissipation efficiency measurement method as claimed in claim 9, wherein
said substrate is made of ceramic material.

11. The solar cell element heat dissipation efficiency measurement method as claimed in claim 9, wherein
said heat dissipation plate is made of aluminum.

12. The solar cell element heat dissipation efficiency measurement method as claimed in claim 8, wherein
when said solar cell element emits light after being applied a forward bias, a step of observing uniformity of surface light emission of said solar cell chip is further included, so as to determine structure quality of said solar cell chip.

13. The solar cell element heat dissipation efficiency measurement method as claimed in claim 8, wherein
value of said forward bias current is equal to 1.25 times a short circuit current value measured, when outdoor sunlight illuminance of said solar cell chip is 850 W/m².

14. The solar cell element heat dissipation efficiency measurement method as claimed in claim 8, wherein
said material of high emission coefficient is a black lacquer of emission rate of 0.94.
